(19) United States
(12) Patent Application Publication
(10) Pub. No.: US 2006/0043428 A1
(43) Pub. Date: Mar. 2, 2006

(54) Semiconductor devices and optical semiconductor relay devices using same

(75) Inventors: Takashi Nishimura, Hyogo-ken (JP); Mitsuhiko Kitagawa, Tokyo (JP); Ryujiro Saso, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 11/211,441

(22) Filed: Aug. 26, 2005

(30) Foreign Application Priority Data
Aug. 27, 2004 (JP) P2004-248102

(51) Int. Cl. H01L 27/10

(52) U.S. Cl. 257/211

(57) ABSTRACT

Power MISFET 20 includes SIO substrate 4 composed of first silicon substrate 1, BOX layer 2 formed on the front surface of first silicon substrate 1 and silicon substrate 3 formed on BOX layer 2. Second silicon substrate 3 is provided with lightly doped-impurity offset layer 5, P layer 6, N+ source layer 7, and N+ drain layer 8. First gate electrode 10 made of poly crystalline silicon is formed on Player 6 through gate insulation film 9. Second gate electrode 15 is formed on the back surface of first silicon substrate 1 while BOX layer 2 functions as a gate insulation film.

This application is based upon and claims the benefit of priority from the prior Japanese Patent Application No. 2004-248102, filed on Aug. 27, 2004, the entire contents of which are incorporated herein by reference.

### FIELD OF THE INVENTION

This invention generally relates to semiconductor devices and, more particularly, to silicon-on-insulator structured power metal-insulator-semiconductor-field-effect-transistor devices and optical semiconductor relay devices which use the same to transmit high frequency signals in semiconductor testers or the like.

### BACKGROUND OF THE INVENTION

Recently available semiconductor relay devices are provided with light emitting diode (“LED”) devices on the input side and power metal-insulator-semiconductor-field-effect transistor (“MISFET”) devices on the output side. Such semiconductor relay devices are required for the reduction of capacitor Coff at the signal cut-off state and electric resistance Ron defined between the output terminals at the turned-on state as the signal processing speed becomes equal to or higher than an ultra high frequency of GHz.

Silicon-on-insulator (“SOI”) structured power MISFET devices have been used for optical semiconductor relay devices as disclosed in Japanese Unexamined Patent Publication (Tokkaihei) 11-74529. Such SOI structured power MISFET devices have been unable to achieve the reduction of capacitor Coff, electric resistance Ron and the product (Coff×Ron) of capacitor Coff and resistance Ron while maintaining a withstand voltage between the gate and drain electrodes.

### SUMMARY OF THE INVENTION

The first aspect of the present invention is directed to a semiconductor device formed on a silicon-on-insulator substrate. The silicon-on-insulator substrate comprises a first semiconductor substrate, a buried oxide layer formed on a first principal surface of the first semiconductor substrate and a second semiconductor substrate formed on the buried oxide layer. The second semiconductor substrate is composed of a semiconductor layer of a first conductive type semiconductor, an offset layer which is in contact with one end of the semiconductor layer and is more lightly doped in impurity than the semiconductor layer, a heavily doped-impurity source layer of a second conductive type semiconductor provided in contact with the semiconductor layer and a heavily doped-impurity drain layer of the second conductive type semiconductor provided in contact with the offset layer. Further, a first gate insulation film is formed on the semiconductor layer, a first gate electrode is formed on the gate insulation film adjacent to the semiconductor layer, and a second gate electrode is formed on a second principal surface of the first semiconductor substrate.

The second aspect of the present invention is also directed to a semiconductor device formed on a silicon-on-insulator substrate. The silicon-on-insulator substrate comprises a first semiconductor substrate, a buried oxide layer formed on a first principal surface of the first semiconductor substrate and a second semiconductor substrate formed on the buried oxide layer. The second semiconductor substrate is composed of a semiconductor layer made of a first conductive type semiconductor, first and second lightly doped-impurity offset layers made of the first and a second conductive type semiconductors, respectively, which are repeatedly disposed opposite to the semiconductor layer, a heavily doped-impurity source layer of the second conductive type semiconductor provided in contact with the semiconductor layer, and a heavily doped-impurity drain layer of the second conductive type semiconductor provided in contact with the offset layer. Further, a first gate insulation film is formed on the semiconductor layer, a first gate electrode is formed on the gate insulation film adjacent to the semiconductor layer, and a second gate electrode is formed on a second principal surface of the first semiconductor substrate.

The third aspect of the present invention is directed to a semiconductor device formed on a silicon-on-insulator substrate. The silicon-on-insulator substrate includes a first semiconductor substrate, a buried oxide layer formed on a first principal surface of the first semiconductor substrate, and a second semiconductor substrate formed on the buried oxide layer. The second semiconductor substrate is provided with a semiconductor layer made of a first conductive type semiconductor, a lightly doped-impurity offset layer disposed opposite to the semiconductor layer, a heavily doped-impurity source layer of first and second conductive type semiconductors provided in contact with each other opposite to the semiconductor layer, and a heavily doped-impurity drain layer of the second conductive type semiconductor provided in contact with the offset layer. The silicon-on-insulator substrate further includes a gate insulation film formed on the semiconductor layer, a first gate electrode formed on the gate insulation film adjacently to the semiconductor layer, and a second gate electrode formed on a second principal surface of the first semiconductor substrate.

The fourth aspect of the present invention is directed to a semiconductor device formed on a silicon-on-insulator substrate. The silicon-on-insulator substrate includes a first semiconductor substrate, a buried oxide layer formed on a first principal surface of the first semiconductor substrate, and a second semiconductor substrate formed on the buried oxide layer. The second semiconductor substrate is provided with a semiconductor layer made of a first conductive type semiconductor, an offset layer which is provided in the second semiconductor substrate in contact with the semiconductor layer and into which an impurity is more lightly doped than the semiconductor layer, a heavily doped-impurity source layer provided in contact with another end of the semiconductor layer, a back gate layer of the first conductive type semiconductor provided adjacent to the source layer, and a heavily doped-impurity drain layer of the second conductive type semiconductor provided in contact with the offset layer. The silicon-on-insulator substrate further includes a gate insulation film formed on the semiconductor layer, a first gate electrode formed on the gate insulation film adjacently to the semiconductor layer, and a second gate electrode formed on a second principal surface of the first semiconductor substrate.

The fifth aspect of the present invention is directed to a semiconductor device comprises a power MISFET device, first and second MISFET devices, and isolation layers. The power MISFET device includes a silicon-on-insulator substrate having a first semiconductor substrate, a buried oxide layer formed on a first principal surface of the first semiconductor substrate, and a second semiconductor substrate formed on the buried oxide layer. The second semiconductor substrate is provided with a first semiconductor layer made of a first conductive type semiconductor, an offset layer which is provided in the second semiconductor substrate in contact with the first semiconductor layer and into which an impurity is more lightly doped than the first semiconductor layer, a first heavily doped-impurity source layer of a second conductive type semiconductor provided in contact with another end of the first semiconductor layer, a first heavily doped-impurity drain layer of the second conductive type semiconductor provided in the second semiconductor substrate in contact with offset layer. The power MISFET device further includes a first gate insulation film, a first gate electrode provided adjacently to the first semiconductor layer, a second gate electrode connected to the buried oxide layer and formed on the second semiconductor substrate, a heavily doped-impurity drain layer of the second conductive type semiconductor provided in contact with the offset layer, a gate insulation film formed on the semiconductor layer, a first gate electrode formed on the gate insulation film adjacently to the semiconductor layer, and a second gate electrode formed on a second principal surface of the first semiconductor substrate. The first MISFET device includes a second semiconductor layer provided in the second semiconductor substrate, a second heavily doped-impurity source layer of the second conductive type semiconductor provided in the second semiconductor substrate in contact with one end of the second semiconductor layer, a second heavily doped-impurity drain layer of the second conductive type semiconductor provided in the second semiconductor substrate in contact with another end of the second semiconductor layer, a second gate insulation film, and a third gate electrode provided adjacently to the second semiconductor layer. The second MISFET device includes a third semiconductor layer of the second conductive type semiconductor provided in the second semiconductor substrate, a third heavily doped-impurity source layer of the first conductive type semiconductor provided in the second semiconductor substrate in contact with one end of the third semiconductor layer, a third heavily doped-impurity drain layer of the first conductive type semiconductor provided in the second semiconductor substrate in contact with another end of the third semiconductor layer, a third gate insulation film, and a fourth gate electrode provided on the third gate insulation film adjacently to the second semiconductor layer. The isolation layers are provided in the second semiconductor substrate to isolate the power MISFET device, first and second MISFET devices from each other.

The sixth aspect of the present invention is directed to an optical semiconductor relay device provided with a power MISFET device. The MIDFET device includes a light emitting element to emit light in response to a relay control signal, a photodiode array to generate a voltage in response to the light emitted from the light emitting element and a silicon-on-insulation substrate. The silicon-on-insulation substrate has a first semiconductor substrate, an oxide layer buried in the first semiconductor substrate, and a second semiconductor substrate provided on a first principal surface of the oxide layer. The second semiconductor substrate includes a semiconductor layer of a first conductive type semiconductor, an offset layer which is provided in contact with one end of the semiconductor layer and into which an impurity is more lightly doped than the semiconductor layer, a highly doped-impurity source layer of the second conductive type semiconductor formed, and a highly doped-impurity drain layer of the second conductive type semiconductor provided in contact with the offset layer. The MIDFET device further includes a source electrode connected to the source layer, a gate insulation film, a first gate electrode formed on the gate insulation film adjacently to the semiconductor layer, and a second gate electrode provided on a second principal surface of the first semiconductor substrate. An output voltage of the photodiode array is supplied between the first and second gate electrodes and the source electrode.

### BRIEF DESCRIPTION OF THE DRAWINGS

A more complete appreciation of the present invention and many of its attendant advantages will be readily obtained as the same becomes better understood by reference to the following detailed descriptions when considered in connection with the accompanying drawings, wherein:

FIG. 1 is a cross-sectional view of a power MISFET device in accordance with the first embodiment of the present invention;

FIG. 2 is a schematic diagram to explain operations of the power MISFET device shown in FIG. 1;

FIG. 3 is a characteristic diagram to show an electric resistance at the turned-on state;

FIG. 4 is a cross-sectional view of a power MISFET device modified to the first embodiment of the present invention;

FIG. 5 is a cross-sectional view of a power MISFET device further modified to the first embodiment of the present invention;

FIG. 6 is a schematic plan view of a power MISFET device in accordance with the second embodiment of the present invention;

FIG. 7 is a characteristic diagram to show an electric resistance at the turned-on state;

FIG. 8 is a circuit diagram of an optical semiconductor relay device in accordance with the third embodiment of the present invention;

FIG. 9 is a cross-sectional view of a semiconductor device in accordance with the fourth embodiment of the present invention;

FIG. 10 is a cross-sectional view of a power MISFET device in accordance with the fifth embodiment of the present invention;

FIG. 11 is a schematic diagram to explain operations of the power MISFET device shown in FIG. 10;

FIG. 12 is a schematic plan view of the power MISFET device shown in FIG. 10;

FIG. 13 is a cross-sectional view of a power MISFET device in accordance with the sixth embodiment of the present invention;

FIG. 14 is a schematic diagram to explain operations of the power MISFET device shown in FIG. 13; and

FIG. 15 is a schematic plan view to explain operations of the power MISFET device shown in FIG. 13.

### DETAILED DESCRIPTION OF THE INVENTION

Embodiments of the present invention will be explained below with reference to the attached drawings. It should be noted that the present invention is not limited to the embodiments but covers their equivalents. Throughout the attached drawings, similar or same reference numerals show similar, equivalent or same components. The drawings, however, are shown schematically for the purpose of explanation so that their components are not necessarily the same in shape or dimension as actual ones. In other words, concrete shapes or dimensions of the components should be considered as described in these specifications, not in view of the ones shown in the drawings. Further, some components shown in the drawings may be different in dimension or ratio from each other.

### First Embodiments

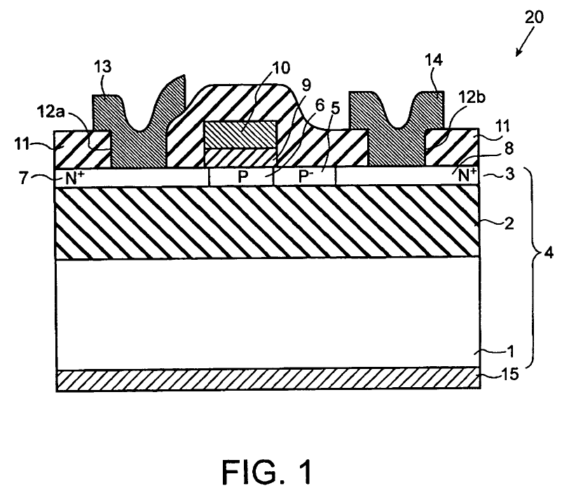

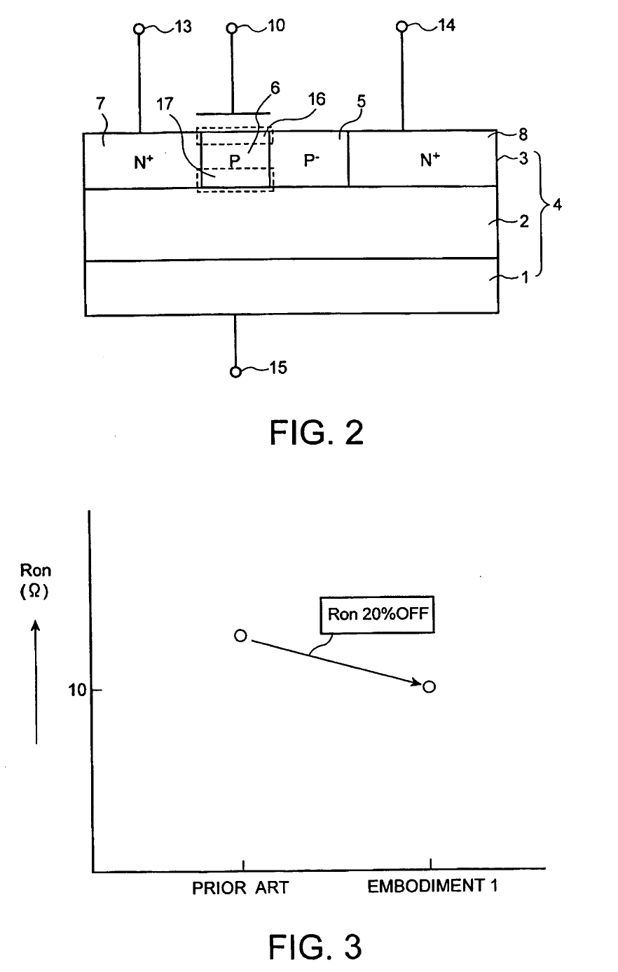

A semiconductor device in accordance with the first embodiment of the present invention will be described below with reference to FIGS. 1 and 2. The first embodiment is directed to an SOI structured power MISFET device to be applied to an optical semiconductor relay device. FIG. 1 is a cross-sectional view of the power MISFET device and FIG. 2 shows a schematic diagram of the operation of the power MISFET device.

As shown in FIG. 1, power MISFET device 20 has SOI substrate 4 in which buried oxide (BOX) layer 2 is formed on first silicon substrate 1 and second silicon substrate 3 is formed on BOX layer 2. In other words, SOI substrate 4 is composed of first and second silicon substrates 1 and 3 and BOX layer 2 which is made by the oxidization of a silicon film at a high temperature and which is disposed between first and second silicon substrates 1 and 3. First silicon substrate 1 contains an N type doped impurity, i.e., an N type semiconductor but may have a P type doped impurity, i.e., a P type semiconductor, instead.

Second silicon substrate 3 is provided with P-offset layer 5, P layer 6, and N+ source and drain layers 7 and 8 formed on BOX layer 2. P layer 6 is in contact with P-offset layer 5 at one end and N+ source layer 7 at another end, respectively. P layer 6 functions as a base layer of power MISFET device 20.

P-offset layer 5 is designed to enhance a withstand voltage between the source and drain electrodes. Further, P-offset layer 5 is also designed to substantially reduce capacitor Cgd defined between first gate and drain electrodes 10 and 14 and capacitor Csd defined between source and drain electrodes 13 and 14. Second silicon substrate 3 is made so thin in thickness as 0.1 μm to reduce capacitors: capacitors Cgd and Csd. Capacitor Coff, defined between the output terminals at the signal cut-off state, can be expressed by the following:
Coff=Cgd+Csd+Cg2d (1)
where Cgd and Csd have a high ratio, i.e., (Cgd+Csd)>>Cg2d.

First gate electrode 10 made from poly-crystalline silicon is provided on P layer 6 and extends its width over parts of N+ source and drain layers 7 and 8. First gate electrode 10 is covered with insulation film 11 in which contact holes 12a and 12b are provided to expose parts of N+ source and drain layers 7 and 8. In order to maintain a withstand voltage of the power MISFET device gate insulation film 9 is thicker in thickness than gate insulation films provided for digital semiconductor devices such as memory devices and logic gates.

Source and drain electrodes 13 and 14 are formed on exposed N+ source and drain layers 7 and 8, respectively. Second gate electrode 15 is provided on the back of first silicon substrate 1 and BOX layer 2 is a gate insulator for second gate electrode 15.

As shown in FIG. 2, power MISFET device 20 has first and second channel portions 16 and 17 which are defined when first and second gate electrodes 10 and 15 are supplied with first and second gate operation voltages, respectively.

Here, BOX layer 2 is thicker in thickness than gate insulation film 9 (shown in FIG. 1). The thickness of BOX layer 2 is 3 μm while that of gate insulation film is 0.14 μm, for instance. The thickness of the former is at least a number one decimal place more than the latter. Thus, threshold voltage Vth2 of power MISFET device 20 at the time when second gate electrode 15 and drain electrode 14 are supplied with a positive voltage (i.e., the voltage at which second channel portion 17 is conductive or turned on) is greater than threshold voltage Vth1 of power MISFET device 20 at the time when first gate electrode 10 and drain electrode 14 are supplied with a positive voltage (i.e., the voltage at which first channel portion 16 is conductive or turned on). Threshold voltage Vth2 is not less by four times, for example, than threshold voltage Vth1.

Threshold voltage Vth3 of power MISFET device 20 at the time when first and second gate electrodes 10 and 15 and drain electrode 14 are supplied with a positive voltage (i.e., the voltage at which first and second channel portions 16 and 17 are conductive or turned on) can be expressed by the following:
Vth3<Vth1<Vth2 (2)
In short, threshold voltage Vth3 can be lower than threshold voltage Vth1.

Here, since the thickness of BOX layer 2 is at least a number one decimal place more than gate insulation film 9, capacitor Cgd defined between gate and drain electrodes 10 and 14 and capacitor Csd defined between source and drain electrodes 13 and 14 can be suppressed at the time when second gate electrode 15 is supplied with a positive voltage. Further, as channel portion 17 becomes worse in interface state, mobility or the like, power MISFET device 20 provided with second gate electrode 15 as a gate electrode becomes worse in characteristic. Thus, it is desirable to make second channel portion 17 the same crystallization as first channel portion 16.

Next, characteristics of power MISFET devices will be explained with reference to FIG. 3 in which turned-on resistance characteristic of a prior art MISFET device is shown at the time when a positive voltage is applied to the gate and drain electrodes and that of the MISFET device in accordance with the present invention is shown at the time when a positive voltage is applied to first and second gate electrodes 10 and 15 and drain electrode 14.

As shown in FIG. 3, the turned-on resistance of the prior art power MISFET device is bigger than that of power MISFET device 20 of the present invention. The same positive voltage is applied to first and second gate electrodes 10 and 15 while a positive voltage is applied to drain electrode 14 in this embodiment. Thus, first and second channel portions 16 and 17 are turned on at the same time, so that the turned-on resistance of power MISFET device 20 can be reduced more than that of the prior art MISFET device.

Referring now to FIG. 2, as set forth above, the semiconductor device of this embodiment is provided with lightly doped-impurity offset layer 5 to improve a withstand voltage between source and drain electrodes 13 and 14. As will be described later on, offset layer 5 can be replaced by super junction structured layers which are fine in pitch and which are designed to make depletion layers in the thermal equilibrium state at the time when zero voltage is applied to gate and drain electrodes 10 and 14. Power MISFET device 20 includes first gate electrode 10, gate insulation film 9, P layer 6, BOX layer 2, first silicon substrate 1 and second gate electrode 15. First gate electrode 10 is formed over P layer 6 through gate insulation film 9 (shown in FIG. 1) while BOX layer 2 provided as a gate insulation film and second gate electrode 15 are formed on the front and back (first and second principal) surfaces of first silicon substrate 1, respectively. The threshold voltage at the time when first and second gate electrodes 10 and 15 are supplied with positive voltages so that first and second channel portions 16 and 17 are turned on can be made smaller than the threshold voltage at the time when first gate electrode 10 is supplied with a positive voltage so that first channel portion 16 is turned on. Thus, SOI structured power MISFET devices can be provided with the reduction of capacitor Coff defined between the output terminals at the signal cut-off state and electric resistance Ron at the turned-on state.

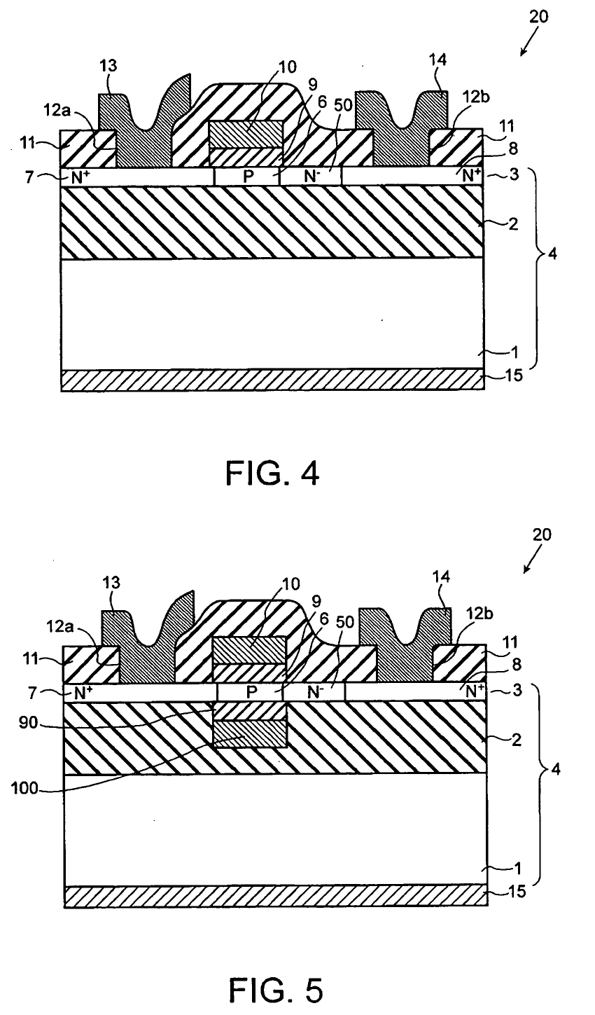

Although P-offset layer 5 is used in the embodiment, a lightly doped-impurity, high resistance N-offset layer 50 may be also used as shown in FIG. 4. As an alternative configuration modified to this embodiment, third gate insulation film and electrode 90 and 100 may be provided in BOX layer 2 with substantially the same structure as first gate insulation film and electrode 9 and 10, respectively, as shown in FIG. 5. Further, instead of the provision of second gate electrode 15 formed on the back surface of first silicon substrate 1, a lead is provided to supply a voltage through a welding material in the case that a power MISFET device is sealed in a resin sealed semiconductor device. In addition, a power MOSFET with a silicon oxide gate insulation film can be used in place of power MISFET 20 with gate insulation film 9.

### Second Embodiment

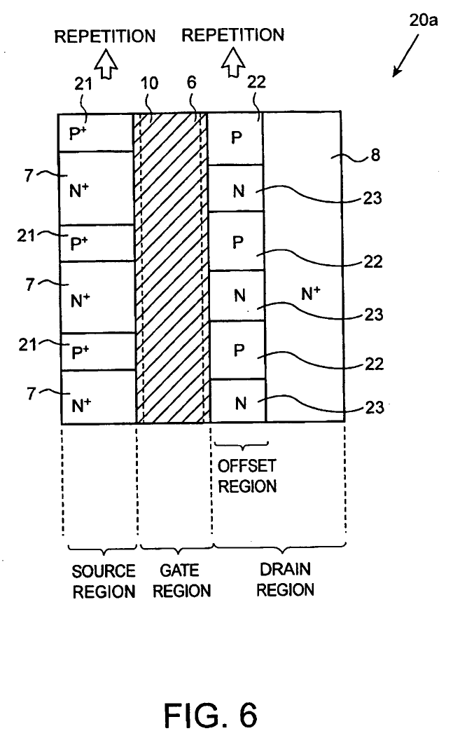

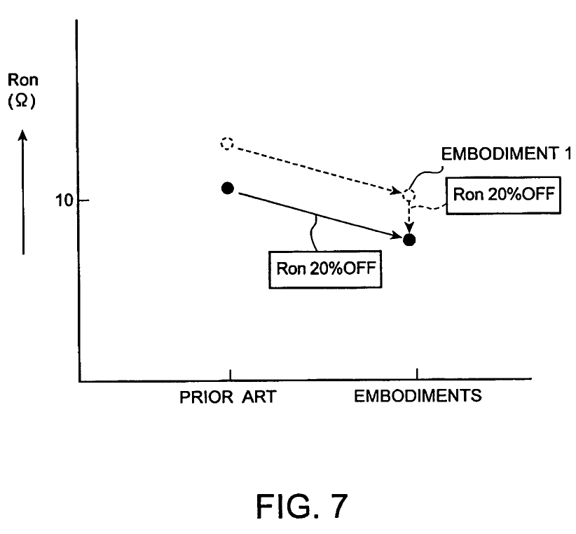

Next, the second embodiment in accordance with the present invention will be described below with reference to FIGS. 6 and 7. FIG. 6 is a schematic plan view of a power MISFET device of the second embodiment. A source region of a power MISFET device of this embodiment corresponding to that of the first embodiment is composed of an N+ layer and P+ back gate layer. A drain region of the power MISFET device corresponding to that of the first embodiment is provided with a super junction structure.

Since the power MISFET device of this embodiment is the same in structure as that of the first embodiment except such a super junction structure, explanation about the same reference numerals and symbols used will be omitted while only different portions will be explained below.

As shown in FIG. 6, offset portions with the super junction structure are made in the drain region of power MISFET device 20a. A plurality of minute-width N+ source layers 7 and P+ offset layers 21 are disposed side by side in the source region provided opposite to a gate region while a plurality of minute-width P and N offset layers 22 and 23 are also disposed side by side in the offset portion in the drain region provided opposite to the gate region. Although the width of N+ source layer 7 is wider than that of P+ offset layer 21 in the disposition of N+ source layer 7 and P+ offset layer 21 as shown FIG. 6, the width of N+ source layer 7 may be designed to be substantially equal to or narrower than that of P+ offset layer 21. The same disposition in terms of the widths may be applied to that of N offset layer 23 and P offset layer 22. P+ offset layer 21 is electrically connected to the source electrodes, functioning as a back gate electrode to stabilize a potential of P (base) layer 6.

P and N offset layers 22 and 23 of the super junction are designed to be sufficiently narrower in width than each of the depletion layers defined in PN junctions in the offset portion at the thermal equilibrium. With those structures, capacitor Cds defined between the drain and source regions and capacitor Cgd defined between the gate and drain regions can be made smaller than those of the first embodiment. Further, since the depletion layers are filled with electrons generated at the time when a positive voltage is applied to gate region 10 and becomes lower in electric resistance, turned-on resistance Ron of power MISFET device 20a can be substantially reduced.

Referring now to FIG. 7, a characteristic of power MISFET device 20a will be described. FIG. 7 shows turned-on resistance characteristics which represents a prior art at the time when a first gate electrode is supplied with a positive voltage and power MISFET device 20a at the time when first and second gate electrodes 10 and 15 are supplied with a positive voltage.

Turned-on resistance Ron of the prior art MISFET device is large as shown in the upper left dotted circle in FIG. 7. First and second gate electrodes 10 and 15 of power MISFET device 20a are supplied with the same positive voltage while drain electrode 14 is supplied with a positive voltage. Thus, since first and second channel portions 16 and 17 are turned on at the same time, turned-on resistance Ron of power MISFET device 20a is reduced more than that of the prior art MISFET device. Further, when the positive voltage is applied to gate electrodes 10 and 15, the depletion layers are filled with electrons and turned-on resistance Ron of power MISFET device 20a is reduced 20% more than that of power MISFET device 20 of the first embodiment, such further 20% reduction being shown by a vertical dotted line and arrow in FIG. 7.

As set forth above, N+ source layers 7 and P+ offset layers 21 in the source region and P and N offset layers of the drain region are sufficiently narrower in width than each of the depletion layers defined in their PN junctions at the thermal equilibrium in addition to the provision of first and second gate electrodes 10 and 15. The threshold voltage at the time when first and second gate electrodes 10 and 15 are supplied with a positive voltage can be smaller than that at the time when first gate electrode 10 is supplied with a positive voltage. Thus, SOI structured power MISFET device 20a can be provided with significantly reduced capacitor Coff defined between the output terminals at the signal cut-off state and with remarkably reduced turned-on resistance Ron in comparison with the first embodiment.

### Third Embodiment

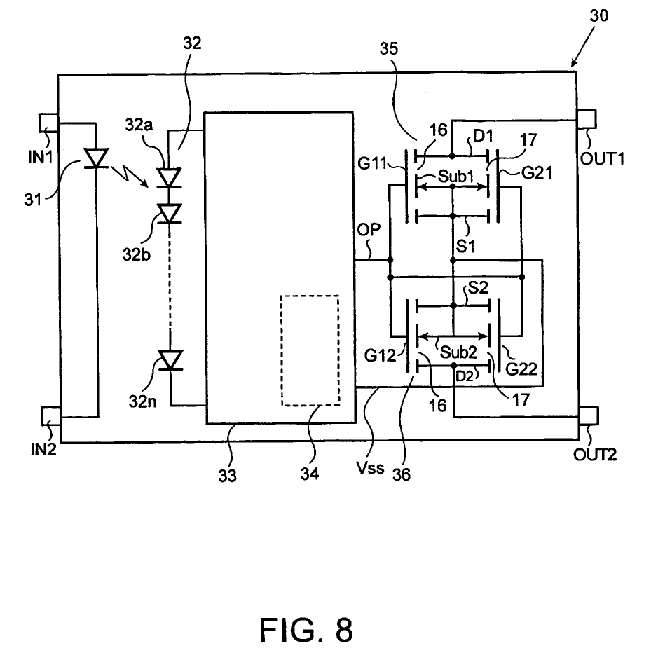

An optical semiconductor relay device of the third embodiment in accordance with the present invention will be described with reference to a circuit diagram shown in FIG. 8. The SOI structured power MISFET device of the first embodiment is used in this embodiment.

As shown in FIG. 8, optical semiconductor relay device 30 includes LED device 31, photodiode array 32, control circuit 33 and power MISFET devices 35 and 36. Optical semiconductor relay device 30 is sealed in a 4-pin resin sealed package.

LED device 31 is a GaAs infrared LED device connected to input terminals IN1 and IN2. When a relay control signal is applied between input terminals IN1 and IN2, LED device 31 emits light. The light is received by photodiode array 32 provided opposite to, and separated at a distance from, LED device 31.

Photodiode array 32 is composed of a cascade connection of “n” photodiodes 32a, 32b, . . . , 32n. When photodiode array 32 receives the light from LED device 31, photodiodes 32a, 32b, . . . , 32n connected in a cascade generate a DC voltage of electromotive force “n” times each motive force generated between both output terminals of respective photodiodes 32a, 32b, . . . , 32n. The DC voltage is supplied between input terminals of control circuit 33.

Control circuit 33 transmits an output signal in response to the DC voltage to first and second gate electrodes G11 and G21 of power MISFET device 35 and to first and second gate electrodes G12 and G22 of power MISFET device 36. Control circuit 33 contains discharge circuit 34 to rapidly discharge electric charges stored in power MISFET devices 35 and 36.

Source and back gate electrodes S1 and Sub1 of power MISFET device 35 are connected to low power source Vss of control circuit 33 and drain electrode D1 is connected to output terminal OUT1. Source and back gate electrodes S2 and Sub2 of power MISFET device 36 are connected to low power source Vss of control circuit 33 and drain electrode D2 is connected to output terminal OUT2.

When output signal OP is applied to first and second gate electrodes G11 and G21 of power MISFET device 35 and first and second gate electrodes G21 and G22 of power MISFET device 36, channel portions 16 and 17 of power MISFET devices 35 and 36 are turned on, output terminals OUT1 and OUT2 become conductive and optical semiconductor relay device 30 [You rename 30 from “device” to “circuit” here which I assume is intentional.] is turned on.

When no relay control signal is supplied between input terminals IN1 and IN2, LED device 31 stop emitting light so that zero DC voltage is applied between both terminals of photodiode array 32. Thus, output signal OP of control circuit 33 becomes zero voltage, power MISFET devices 35 and 36 are turned off, no conductive state is set up between output terminals OUT1 and OUT2, and optical semiconductor relay device 30 is turned off.

Since the SOI structured power MISFET devices in which capacitor Coff defined between output terminals during a signal cut-off period and turned-on resistance Ron are reduced are used in the optical semiconductor relay device 30 of the present embodiment as described above, an electric resistance defined between output terminals OUT1 and OUT2 of the optical semiconductor relay device can be made small at the time when the optical semiconductor relay device is turned on.

Further, since capacitor Cds defined between the source and drain electrodes of the MISFET device at the time when the optical semiconductor device is turned off, the quantity of electric charges stored at the turned-on state can be reduced. Thus, switching time of the optical semiconductor relay device from the turned-on state to the turned-off state is shortened.

### Fourth Embodiment

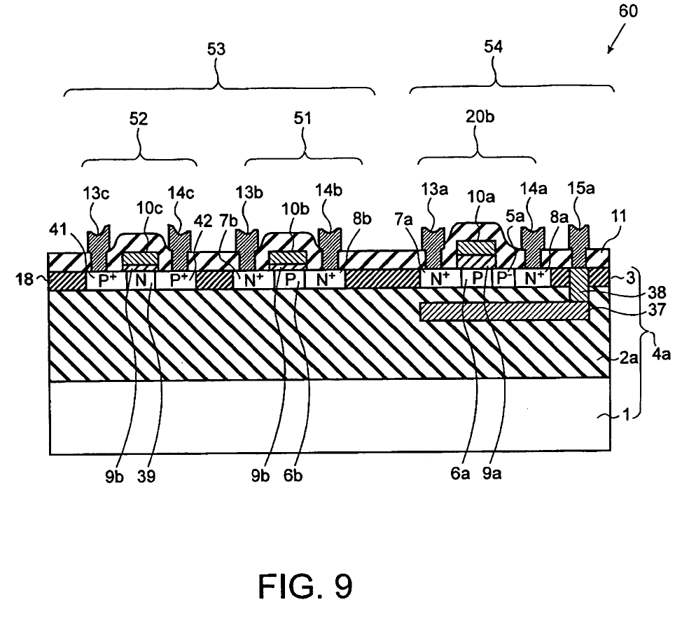

A semiconductor device of the fourth embodiment in accordance with the present invention will be described below with reference to its cross sectional view shown in FIG. 9. A power MISFET device and logic MISFET devices are provided on the same SOI substrate in the present embodiment.

Since elements of this embodiment have reference numerals which are similar to, or the same as, those of the first embodiment, explanations about the elements of the similar or same reference numerals will be omitted but those about only different elements will be made below.

As shown in FIG. 9, semiconductor device 60 includes SOI substrate 4a provided with first silicon substrate 1, BOX layer 2a and second silicon substrate 3a. BOX layer 2a is formed on the front surface of first silicon substrate 1. Silicon layer 37 is selectively buried in BOX layer 2a. Second silicon substrate 3a is formed on the front surface of BOX layer 2a. Logic section 53 has N-channel MISFET (first MISFET) device 51 and P-channel MISFET (second MISFET) device 52. Power MISFET device section 54 is composed of power MISFET device 20b and second gate electrode 15a connected to buried silicon layer through plug 38.

Buried silicon layer 37 is provided in BOX (buried oxide) layer 2a. SOI substrate 4a is formed by binding first and second silicon substrates 1 and 3 through BOX layer 2a. Buried silicon layer 37 contains an N-type impurity.

Device isolation layers 18 are formed on BOX layer 2a to isolate N-channel MISFET device 51, P-channel MISFET device 52, and power MISFET device 20b from each other in second silicon substrate 3. [I wanted to make extra clear that 51 and 52 are also separated by 18, though you do so below.] N+ drain layer 8a, P-offset layer 5a, P layer 6a and N+ source layer 7a of power MISFET device 20b are disposed between device isolation layers 18. Plug 38 made of N+ polycrystalline silicon is provided in device isolation layer 18. N+ drain layer 8b, P layer 6b and N+ source layer 7b of N-channel MISFET device 51 are disposed between device isolation layers 18. Similarly, P+ drain layer 42, N layer 39 and P+ source layer 41 of P-channel MISFET device 52 are disposed between device isolation layers 18.

P layer 6a of power MISFET device 20b is provided in contact with P-offset layer 5a at one end and N+ source layer 7a at another end. N+ drain layer 8a is provided in contact with P-offset layer 5a. P layer 6b of P-channel MISFET device 51 is provided in contact with N+ source layer 7b at one end and N+ drain layer 8b at another end. N layer 39 of P-channel MISFET device 52 is provided in contact with P+ source layer 41 at one end and P+ drain layer 42 at another end.

Here, second silicon substrate 3 is relatively thin in thickness, e.g., 0.1 μm, to reduce capacitor Cgd defined between the gate and drain electrodes, capacitor Csd defined between the source and drain electrodes and capacitor Cdsub defined between the drain electrode and the substrate. Buried silicon layer 37 is provided under the region of P-offset layer 5a, P layer 6a, N+ source layer 7a and N+ drain layer 8a. Buried silicon layer 37, however, may be provided only immediately under P layer 6a and a minimum region of P-offset layer 5a and N+ source layer 7a to form the second channel.

Gate electrode 10a is provided on gate insulation film 9a which is formed on P layer 6a of power MISFET device 20b. Gate electrode 10a and gate insulation film 9a are further extended to parts of N+ source layer 7a and P-offset layer 5a. Gate electrode 10a is made of polycrystalline silicon. Gate electrode 10b is provided on gate insulation film 9b which is formed on P layer 6b of N-Channel MISFET device 51. Gate electrode 10b and gate insulation film 9b are further extended to parts of N+ source layer 7b and N+ drain layer 8b. Gate electrode 10b is made of polycrystalline silicon.

Gate electrode 10c is provided on gate insulation film 9b which is formed on N layer 39 of P-channel MISFET device 52. Gate electrode 10c and gate insulation film 9b are further extended to parts of P+ source layer 41 and P+ drain layer 42. Gate electrode 10c is made of polycrystalline silicon. Gate electrodes 10a, 10b and 10c are the same in structure and fabricated in the same process.

Gate electrodes 10a, 10b and 10c are covered with insulation film 11. Insulation film 11 has contact holes to expose parts of N+ source layer 7a, N+ drain layer 8a, N+ source layer 7b, N+ drain layer 8b, P+ source layer 41, P+ drain layer 42 and plug 38, respectively. In order to maintain a withstand voltage of power MISFET device 20b gate insulation film 9a is thicker in thickness than gate insulation film 9b of logic section 53 used for a digital semiconductor circuit.

Source and drain electrodes 13a and 14a are formed on exposed N+ source and drain layers 7a and 8b, respectively. Similarly, source and drain electrodes 13b and 14b are formed on exposed N+ source and drain layers 7b and 8b, respectively. Further, source and drain electrodes 13c and 14c are formed on exposed P+ source and drain layers 41 and 42, respectively. Second gate electrode 15a is formed on exposed plug 38.

As described above, the semiconductor devices of this embodiment are composed of power MISFET device section 54 and, N-channel and P-channel MISFET devices 51 and 52 formed on SOI substrate 4a. Power MISFET device section 54 is provided with second gate electrode 15a connected to buried silicon layer 37 through plug 38 and gate electrode 10a of power MISFET device 20b in which capacitor Coff defined between the output terminals at the signal cut-off state and turned-on resistance are reduced. Further gate electrodes 10a, 10b and 10c are the same in structure, manufactured in the same process and isolated from each other by device isolation layers 18.

By virtue of this embodiment, a high speed power MISFET device with a low CR product (Coff×Ron) and high speed logic MISFET devices with a low operation voltage and a low power consumption are contained in the same semiconductor chip at relatively low cost.

### Fifth Embodiment

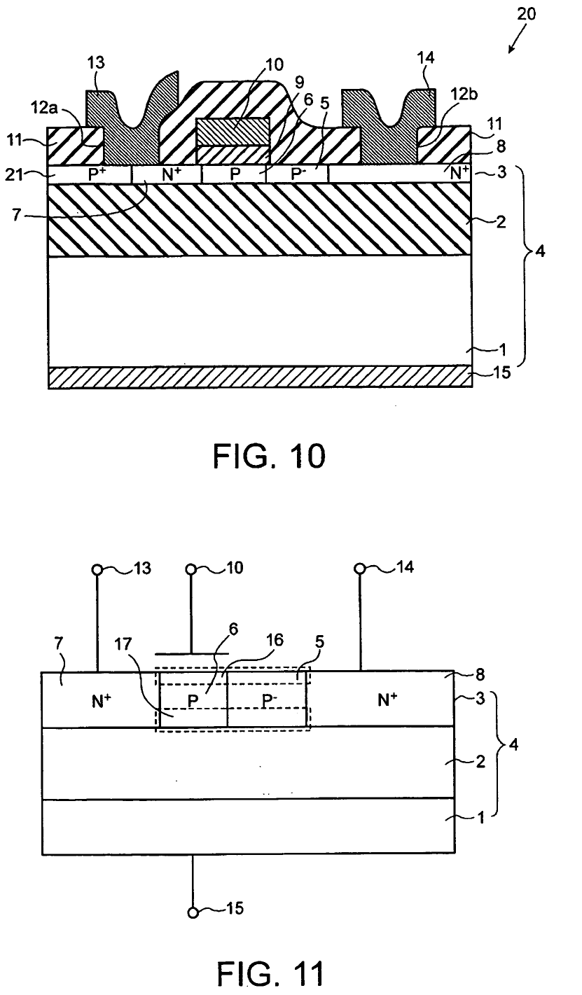

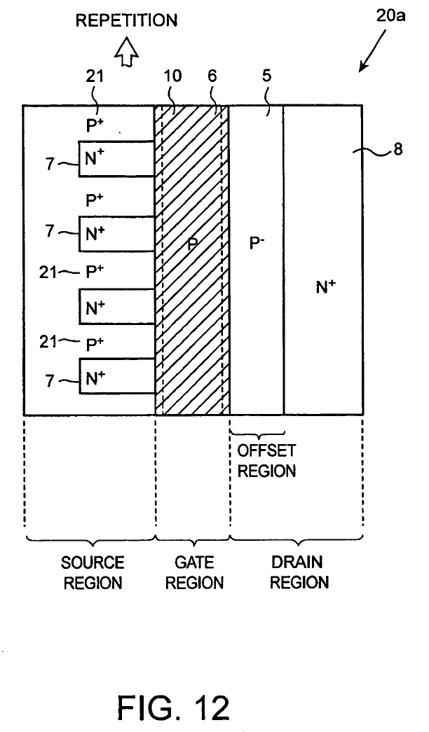

Next, a semiconductor device of the fifth embodiment will be described with reference to FIGS. 10-12. FIG. 10 is a cross-sectional view of a power MISFET device. FIG. 11 is a schematic diagram to explain its operations. FIG. 12 is a schematic plan view of the power MISFET device shown in FIG. 10.

Power MISFET device 20 of this embodiment includes a source region and P-offset region 5. The source region is provided with heavily doped impurity, low resistance P+ back gate layer 21 in addition to heavily doped impurity, low resistance N+ source layer 7. The offset region is made of lightly doped impurity, high resistance P-offset layer 5, only. FIG. 12 shows a schematic plan view of power MISFET device 20. The width of P+ back gate layer 21 is substantially equal to that of N+ source layer 7. The length of P+ back gate layer 21, however, is longer than that of N+ source layer 7 and surrounds N+ source layer 7. Back gate layer 21 is connected to a predetermined voltage to make substrate 3 fixed in potential. Except for those arrangements, power MISFET device 20 of this embodiment is the same in structure as that of the first embodiment.

Referring now to FIG. 11, when a voltage applied to first gate electrode increases to make power MISFET device 20 turn on, channel portions 16 and 17 are formed from P layer 6 through P-offset layer 5. Electrons in P-offset layer 5 arrive at an N+ drain region by diffusion so that P-offset layer 5 may be called a P-drift layer. Further, since P-offset layer 5 improves a withstand voltage as set forth above, it may alternatively called a resurf (reduced surface field) layer.

### Sixth Embodiment

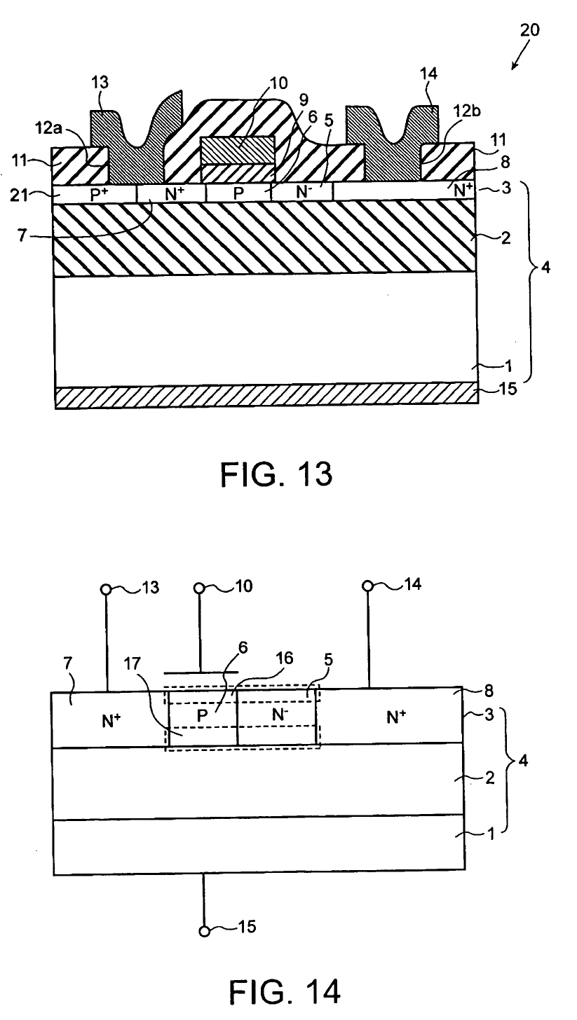

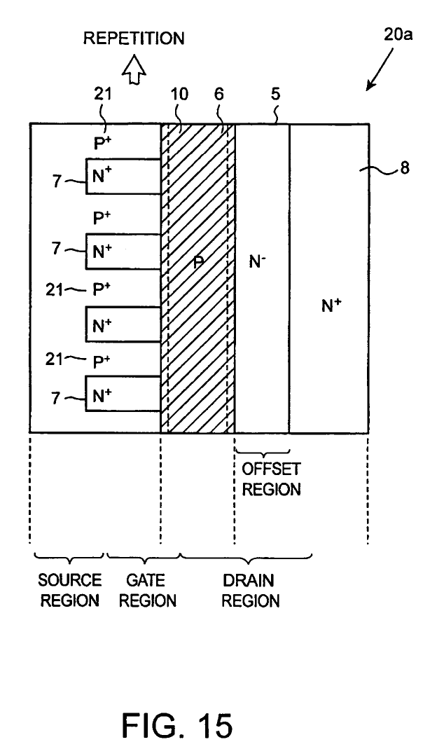

A semiconductor device of the sixth embodiment will be described with reference to FIGS. 13-15. FIG. 13 is a cross-sectional view of a power MISFET device in accordance with the sixth embodiment of the present invention. FIG. 14 is its schematic diagram to explain its operation. FIG. 15 is a schematic plan view of the power MISFET device shown in FIG. 13.

As shown in FIG. 13, power MISFET device 20 of this embodiment includes a source region and an offset region. The source region is provided with heavily doped impurity, low resistance P+ back gate layer 21 in addition to heavily doped impurity, low resistance N+ source layer 7 provided in contact with one end of P layer 6. The offset region provided in contact with another end of P layer 6 is made of lightly doped impurity, high resistance N-layer 5. Referring now to FIG. 15, only N-layer 5 is disposed opposite to P layer 6 while P+ back gate layer 21 [21 is not pictured in FIG. 14 but I assume such in intended. Please reconfirm.]and N+ source layer 7 are disposed opposite to P layer 6 side by side. Similarly to power MISFET device 20 of the fifth embodiment, P+ back gate layer 21 and N+ source layer 7 are equal in width to each other but P+ back gate layer 21 is longer in length than N+ source layer 7 and surrounds N+ source layer 7. P+ back gate layer 21 is connected to a predetermined voltage to make substrate 3 fixed in potential.

As shown in FIG. 14, when a voltage applied to first gate electrode 10 increases to make power MISFET device 20 turn on, channel portions 16 and 17 are formed from P layer 6 through N-offset layer 5. Electrons in N-offset layer 5 arrive at an N+ drain region through N-offset layer by diffusion so that N-offset layer 5 may be called a drift layer. Further, since N-offset layer 5 function as improvement of a withstand voltage as set forth above, it may alternatively called a resurf (reduced surface field) layer.

Although the embodiments include the SOI substrate composed of first and second silicon substrates and BOX layer, the second silicon substrate may be replaced by a SiC substrate.

The present invention is not limited to the embodiments but may be subjected to various modifications without departing from the scope of the invention defined in the attached claims.

In the foregoing description, certain terms have been used for brevity, clearness and understanding, but no unnecessary limitations are to be implied therefrom beyond the requirements of the prior art, because such words are used for descriptive purposes herein and are intended to be broadly construed. Moreover, the embodiments of the improved construction illustrated and described herein are by way of example, and the scope of the invention is not limited to the exact details of construction. Having now described the invention, the construction, the operation and use of embodiments thereof, and the advantageous new and useful results obtained thereby; the new and useful construction, and reasonable equivalents thereof obvious to those skilled in the art, are set forth in the appended claims.

What is claimed is:

1. A semiconductor device comprising:
a silicon-on-insulator substrate having a first semiconductor substrate, a buried oxide layer formed on a first principal surface of the first semiconductor substrate and a second semiconductor substrate formed on the buried oxide layer,
the second semiconductor substrate being provided with a semiconductor layer made of a first conductive type semiconductor, an offset layer which is provided in contact with one end of the semiconductor layer and into which an impurity is more lightly doped than the semiconductor layer;
a heavily doped-impurity source layer of a second conductive type semiconductor provided in contact with the semiconductor layer;
a heavily doped-impurity drain layer of the second conductive type semiconductor provided in contact with the offset layer;
a gate insulation film formed on the semiconductor layer;
a first gate electrode formed on the gate insulation film adjacently to the semiconductor layer; and
a second gate electrode formed on a second principal surface of the first semiconductor substrate.

2. A semiconductor device according to claim 1, wherein the offset layer is made of the first conductive type semiconductor.

3. A semiconductor device according to claim 1, wherein the offset layer is made of the second conductive type semiconductor.

4. A semiconductor device comprising:
a silicon-on-insulator substrate having a first semiconductor substrate,
a buried oxide layer formed on a first principal surface of the first semiconductor substrate, and
a second semiconductor substrate formed on the buried oxide layer,
the second semiconductor substrate being provided with a semiconductor layer made of a first conductive type semiconductor,
first and second lightly doped-impurity offset layers made of a first and a second conductive type semiconductors, respectively, which are repeatedly disposed opposite to the semiconductor layer,
a heavily doped-impurity source layer of the second conductive type semiconductor provided in contact with the semiconductor layer, and
a heavily doped-impurity drain layer of the second conductive type semiconductor provided in contact with the first and second offset layers;
a gate insulation film formed on the semiconductor layer;
a first gate electrode formed on the gate insulation film adjacently to the semiconductor layer; and
a second gate electrode formed on a second principal surface of the first semiconductor substrate.

5. A semiconductor device according to claim 1, further comprising a third gate insulator and a third gate electrode which are substantially the same in thickness as the first gate insulator and the first gate electrode, respectively, and which are provided in the buried oxide layer.

6. A semiconductor device comprising:
a silicon-on-insulator substrate having a first semiconductor substrate,
a buried oxide layer formed on a first principal surface of the first semiconductor substrate, and
a second semiconductor substrate formed on the buried oxide layer,
the second semiconductor substrate being provided with a semiconductor layer made of a first conductive type semiconductor,
a lightly doped-impurity offset layer disposed opposite to the semiconductor layer,
a heavily doped-impurity source layer of first and second conductive type semiconductors provided in contact with each other opposite to the semiconductor layer, and
a heavily doped-impurity drain layer of the second conductive type semiconductor provided in contact with the offset layer;
a gate insulation film formed on the semiconductor layer;
a first gate electrode formed on the gate insulation film adjacently to the semiconductor layer; and
a second gate electrode formed on a second principal surface of the first semiconductor substrate.

7. A semiconductor device according to claim 6, wherein the offset layer is made of the first conductive type semiconductor.

8. A semiconductor device according to claim 6, wherein the offset layer is made of the second conductive type semiconductor.

9. A semiconductor device comprising:
a silicon-on-insulator substrate having a first semiconductor substrate,
a buried oxide layer formed on a first principal surface of the first semiconductor substrate, and
a second semiconductor substrate formed on the buried oxide layer,
the second semiconductor substrate being provided with a semiconductor layer made of a first conductive type semiconductor,
an offset layer which is provided in the second semiconductor substrate in contact with the semiconductor layer and into which an impurity is more lightly doped than the semiconductor layer,
a heavily doped-impurity source layer provided in contact with another end of the semiconductor layer,
a back gate layer of the first conductive type semiconductor provided adjacent to the source layer, and
a heavily doped-impurity drain layer of the second conductive type semiconductor provided in contact with the offset layer;
a gate insulation film formed on the semiconductor layer;
a first gate electrode formed on the gate insulation film adjacently to the semiconductor layer; and
a second gate electrode formed on a second principal surface of the first semiconductor substrate.

10. A semiconductor device according to claim 9, wherein the back gate layer is connected to a predetermined potential.

11. A semiconductor device according to claim 9, wherein the offset layer is the first conductive type semiconductor.

12. A semiconductor device according to claim 9, wherein the offset layer is the second conductive type semiconductor.

13. A semiconductor device according to claim 1, wherein the buried oxide layer is thicker than the gate insulation film.

14. A semiconductor device according to claim 4, wherein the buried oxide layer is thicker than the gate insulation film.

15. A semiconductor device according to claim 6, wherein the buried oxide layer is thicker than the gate insulation film.

16. A semiconductor device according to claim 9, wherein the buried oxide layer is thicker than the gate insulation film.

17. A semiconductor device according to claim 6, wherein the highly-doped impurity layer of the first conductive type semiconductor and the highly-doped impurity source layer are disposed in a substantially equal width to each other.

18. A semiconductor device according to claim 9, wherein the highly-doped impurity source layer and the highly-doped impurity back gate layer are provided in contact with the other end of the semiconductor layer, provided opposite to the semiconductor layer, and disposed in a substantially equal width to each other.

19. A semiconductor device comprising a power MISFET device, first and second MISFET devices, and isolation layers, wherein the power MISFET device includes:
a silicon-on-insulator substrate having a first semiconductor substrate,
a buried oxide layer formed on a first principal surface of the first semiconductor substrate, and
a second semiconductor substrate formed on the buried oxide layer,
the second semiconductor substrate being provided with a first semiconductor layer made of a first conductive type semiconductor,
an offset layer which is provided in the second semiconductor substrate in contact with the first semiconductor layer and into which an impurity is more lightly doped than the first semiconductor layer,
a first heavily doped-impurity source layer of a second conductive type semiconductor provided in contact with another end of the first semiconductor layer,
a first heavily doped-impurity drain layer of the second conductive type semiconductor provided in the second semiconductor substrate in contact with offset layer;
a first gate insulation film;
a first gate electrode provided adjacently to the first semiconductor layer;
a second gate electrode connected to the buried oxide layer and formed on the second semiconductor substrate;
a heavily doped-impurity drain layer of the second conductive type semiconductor provided in contact with the offset layer;
a gate insulation film formed on the semiconductor layer;
a first gate electrode formed on the gate insulation film adjacently to the semiconductor layer; and
a second gate electrode formed on a second principal surface of the first semiconductor substrate,
wherein the first MISFET device includes:
a second semiconductor layer provided in the second semiconductor substrate;
a second heavily doped-impurity source layer of the second conductive type semiconductor provided in the second semiconductor substrate in contact with one end of the second semiconductor layer;
a second heavily doped-impurity drain layer of the second conductive type semiconductor provided in the second semiconductor substrate in contact with another end of the second semiconductor layer;
a second gate insulation film; and
a third gate electrode provided adjacently to the second semiconductor layer;
wherein the second MISFET device includes:
a third semiconductor layer of the second conductive type semiconductor provided in the second semiconductor substrate;
a third heavily doped-impurity source layer of the first conductive type semiconductor provided in the second semiconductor substrate in contact with one end of the third semiconductor layer;
a third heavily doped-impurity drain layer of the first conductive type semiconductor provided in the the second semiconductor substrate in contact with another end of the third semiconductor layer;
a third gate insulation film; and
a fourth gate electrode provided on the third gate insulation film adjacently to the second semiconductor layer; and
wherein the isolation layers are provided in the second semiconductor substrate to isolate the power MISFET device, first and second MISFET devices from each other.

20. An optical semiconductor relay device comprising a power MISFET device, the MIDFET device including:
a light emitting element to emit light in response to a relay control signal;
a photodiode array to generate a voltage in response to the light emitted from the light emitting element;
a silicon-on-insulation substrate having a first semiconductor substrate, an oxide layer buried in the first semiconductor substrate, a second semiconductor substrate provided on a first principal surface of the oxide layer, a semiconductor layer of a first conductive type semiconductor provided in the second semiconductor substrate, an offset layer which is provided in the second semiconductor substrate in contact with one end of the semiconductor substrate and into which an impurity is more lightly doped than the semiconductor substrate, a highly doped-impurity source layer of the second conductive type semiconductor provided in the second semiconductor substrate, a source electrode connected to the source layer, a highly doped-impurity drain layer of the second conductive type semiconductor provided in the second semiconductor substrate in contact with the offset layer;
a gate insulation film;
a first gate electrode formed on the gate insulation film adjacently to the semiconductor layer; and
a second gate electrode provided on a second principal surface of the first semiconductor substrate,
wherein an output voltage of the photodiode array is supplied between the first and second gate electrodes and the source electrode.
